(19) United States
(12) Patent Application Publication
(10) Pub. No.: US 2025/0241084 A1
(43) Pub. Date: Jul. 24, 2025

(54) METHOD OF MANUFACTURING AN OPTOELECTRONIC OR PHOTOVOLTAIC DEVICE, AND DEVICE PRODUCED BY THIS METHOD

(71) Applicant: Commissariat à I'Énergie Atomique et aux Énergies Alternatives, Paris (FR)

(72) Inventor: Florian Dupont, Grenoble Cedex 9 (FR)

(73) Assignee: Commissariat à I'Énergie Atomique et aux Énergies Alternatives, Paris (FR)

(21) Appl. No.: 18/287,456

(22) PCT Filed: Apr. 4, 2022
(86) PCT No.: PCT/EP2022/058880

§ 371 Date: Aug. 26, 2024

(30) Foreign Application Priority Data
Apr. 20, 2021 (FR) FR2104098

(51) Int. Cl. H10F 71/00; C23C 14/06; C23C 14/08; H10F 77/12

(52) U.S. Cl. CPC H10F 71/138; C23C 14/0694; C23C 14/08; H10F 77/12

(57) ABSTRACT

A method of manufacturing an optoelectronic or photovoltaic device, including the following successive steps: a) forming, by PLD deposition, an active layer comprising a perovskite material on the upper side of a first charge transport layer; b) depositing, by PLD, a second charge-transport layer of inorganic material on the top face of the active layer.

The present application is based on, and claims the priority of, French patent application No. FR2104098 filed on Apr. 20, 2021 and entitled “ [symbol] [symbol] [symbol] [symbol] [symbol] [symbol] [symbol] [symbol] [symbol] , [symbol] [symbol] [symbol] [symbol] ”, which is considered an integral part of the present description to the extent permitted by law.

### TECHNICAL FIELD

The present description relates generally to optoelectronic or photovoltaic devices. More particularly, it covers a method for manufacturing an optoelectronic or photovoltaic device based on a perovskite material, and a device produced by this method.

### RELATED ART

Diode-type optoelectronic or photovoltaic devices based on perovskite materials have already been proposed. However, known devices of this type have various drawbacks. In particular, these devices generally suffer from reliability problems and have relatively short lifetimes.

### SUMMARY

In one embodiment, an aim is to overcome some or all of the drawbacks of known optoelectronic or photovoltaic devices based on perovskite materials.

To this end, one embodiment provides a method for manufacturing an optoelectronic or photovoltaic device, comprising the following successive steps:
a) forming, by PLD deposition, an active layer comprising a perovskite material on the upper surface of a first charge transport layer;
b) depositing, by PLD deposition, a second charge-transport layer of inorganic material on top of the active layer.

According to one embodiment, steps a) and b) are carried out under vacuum, i.e. at a pressure below atmospheric pressure, with no vacuum break between steps a) and b).

According to one embodiment, the first charge transport layer is deposited by PLD prior to step a).

According to one embodiment, the first charge transport layer deposition step and step a) are carried out under vacuum, i.e. at a pressure below atmospheric pressure, the method not including a vacuum break between these two steps.

According to one embodiment, the method further comprises, prior to the deposition of the first charge transport layer, a step of depositing a lower electrode, for example by PLD deposition, the first charge transport layer then being deposited on the upper face of the lower electrode.

According to one embodiment, the method further comprises, after step b), a step of depositing a top electrode, for example by PLD deposition, on the top face of the second charge transport layer.

According to one embodiment, the top electrode is made of a transparent conductive material.

According to one embodiment, the second charge transport layer is made of titanium dioxide, tin dioxide, nickel oxide or copper oxide.

According to one embodiment, the perovskite material of the active layer is an inorganic perovskite material.

According to one embodiment, the perovskite material of the active layer is an inorganic halogen perovskite material.

According to one embodiment, prior to step a), the first charge transport layer is deposited on the top surface of an integrated circuit previously formed in and on a semiconductor substrate, for example a silicon substrate.

Another embodiment provides an optoelectronic or photovoltaic device comprising a vertical stack comprising a first charge transport layer, an active layer comprising a perovskite material disposed on the upper side of the first charge transport layer, and a second charge transport layer of an inorganic material disposed on the upper side of the active layer.

According to one embodiment, the first charge transport layer is arranged on the top surface of an integrated circuit formed in and on a semiconductor substrate, for example a silicon substrate.

According to one embodiment, the active layer and the second charge transport layer have crystal structures aligned according to an epitaxial relationship.

According to one embodiment, the active layer is a solid monolayer of said perovskite material.

According to one embodiment, the active layer is a stack of multiple quantum wells consisting of alternating quantum well layers of said perovskite material and barrier layers of another semiconductor material.

### BRIEF DESCRIPTION OF THE DRAWINGS

These and other features and advantages will be described in detail in the following non-limiting description of particular embodiments in relation to the accompanying figures, in which:

FIG. 1 is a cross-sectional view schematically illustrating an example of an optoelectronic or photovoltaic device in one embodiment; and

FIG. 2 is a block diagram showing an example of a manufacturing process for the device shown in FIG. 1.

### DESCRIPTION OF EMBODIMENTS

Like features have been designated by like references in the various figures. In particular, structural and/or functional elements common to the various embodiments may have the same references and may have identical structural, dimensional and material properties.

For the sake of clarity, only those steps and elements that are useful for understanding the described embodiments have been illustrated and described in detail. In particular, the complete realization of the optoelectronic or photovoltaic devices described, and in particular of their possible control circuits, has not been detailed, the realization of these devices being within the capabilities of the person skilled in the art from the indications of the present description.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the figures.

Unless otherwise specified, the expressions “about”, “approximately”, “substantially”, and “of the order of” mean to within 10%, preferably to within 5%.

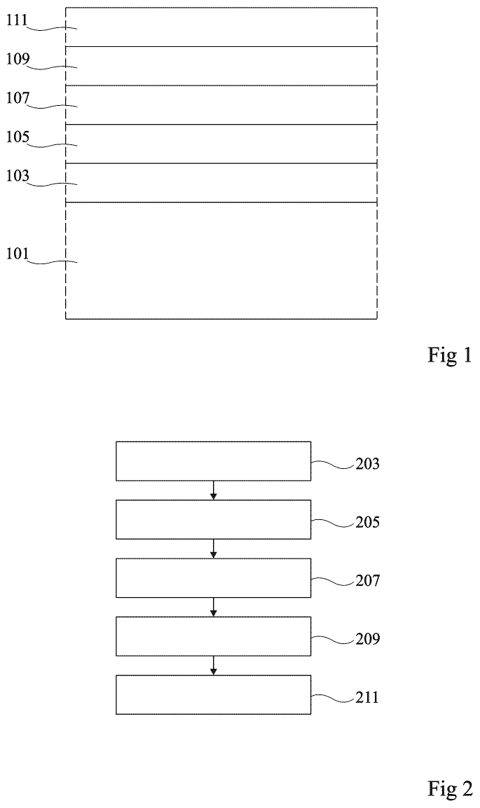

FIG. 1 is a cross-sectional view schematically illustrating an example of an optoelectronic or photovoltaic device according to one embodiment.

The device shown in FIG. 1 is a diode-type device, such as a light-emitting diode, photodiode or photovoltaic diode. The described embodiments are particularly advantageous for the realization of light-emitting diodes, and, more particularly, for the realization of microdisplay pixel light-emitting diodes.

The device shown in FIG. 1 comprises a support substrate 101, for example a semiconductor substrate, such as a silicon substrate.

The device shown in FIG. 1 further comprises a vertical stack comprising, in this order from the top face of the substrate, a first electrode layer 103, a first charge transport layer 105, an active layer 107, a second charge transport layer 109, and a second electrode layer 111.

The lower electrode layer 103 is in contact, for example, with the upper surface of the substrate 101. The first charge transport layer 105 is, for example, in contact, by its lower face, with the upper face of the electrode layer 103. The active layer 107 is in contact, for example, with the upper face of the charge transport layer 105 via its lower face. The second charge transport layer 109 is in contact, for example, with the upper face of the active layer 107. The upper electrode layer 111 is in contact, for example, with the upper face of the charge transport layer 109.

According to one aspect of the described embodiments, the active layer 107 comprises a material with a perovskite structure.

One advantage is that materials with a perovskite structure, also known as perovskite materials, have a high internal quantum efficiency of up to 100%. In addition, perovskite materials have a high absorption coefficient. As a result, the photo-electric conversion function (in the case of a photodiode or photovoltaic diode) or the electro-photonic conversion function (in the case of a light-emitting diode) can be efficiently performed by a relatively thin active layer.

Because of the small thicknesses required to ensure the desired conversion functions, the active layer 107 can be etched easily, enabling the production of light conversion or emission elements with very small lateral dimensions. The methods described are particularly advantageous for the production of diodes in small pixels, for example for the production of devices (e.g. an image display screen) with an inter-pixel pitch of less than 100 μm, for example less than 20 μm, or even less than 5 μm.

A further advantage is that perovskite materials can be deposited at relatively low temperatures, e.g. 400° C. or less, enabling them to be deposited on integrated circuits such as CMOS (Complementary Metal Oxide Semiconductor).

Another advantage is that perovskite materials are highly tolerant to crystal structure defects.

The active layer 107 can be a solid monolayer of perovskite material. The thickness of the active layer 107 is then, for example, between 1 nm and 1 μm.

Alternatively, the active layer 107 can be a multiple-quantum-well stack comprising alternating semiconductor layers of a first material and semiconductor layers of a second material, with each layer of the first material being sandwiched between two layers of the second material. The first material is a perovskite material and has a narrower bandgap than the second material. Each layer of the first material defines a quantum well. The layers of the second material are quantum barriers. The number of quantum wells in the stack is preferably greater than or equal to 2, for example greater than or equal to 3. The material of the barrier layers 103 is preferably an inorganic semiconductor material, for example a III-V compound comprising at least a first group III element, a second group V element and, optionally, a third element, for example a group III element other than the first element. By way of example, the group V element is nitrogen (N), so that the barrier layer material comprises a III-N compound. By way of example, the barrier layer material is gallium nitride, aluminum nitride, boron nitride, indium nitride or an alloy of one or more of these materials. The thickness of the layers of the first material is chosen to enable quantum confinement in each quantum well layer. For example, each layer of the first material has a thickness of between 1 and 50 nm. For example, each barrier layer has a thickness of between 1 and 100 nm. Alternatively, the stack may comprise a single quantum well layer. In this case, the quantum well can be confined between two barrier layers as defined above. Alternatively, one and/or other of the barrier layers may be omitted, the quantum barrier role then being fulfilled by the lower charge transport layer 105 and/or by the upper charge transport layer 109. Similarly, in a multiple-quantum-well stack comprising several quantum-well layers, one and/or other of the stack's extreme barrier layers can be omitted, the quantum-barrier role then being fulfilled by the lower charge transport layer 105 and/or by the upper charge transport layer 109.

Whether the active layer 107 is a massive monolayer or comprises a multiple quantum well stack, to achieve good light conversion or emission performance and long life, the perovskite material of the active layer 107 is preferably an inorganic perovskite material.

For example, a perovskite material based on cesium, lead and one or more halogens may be used, such as CsPbI₂Br, CsPbBr₃, CsPbCl₃, CsSnBr₃, or CsPbI₃. Alternatively, a hybrid perovskite material of the MAPbI₃ type can be used. More generally, other perovskite materials can be chosen depending on the absorption or emission properties required.

In general, a perovskite material known as inorganic halogen is preferred, i.e. of the type ABX₃, where:
A is an inorganic element, for example cesium (Cs), lead (Pb), phosphorus (K) or lithium (Li),
B is lead (Pb), tin (Sn) or germanium (Ge), and
X is a halogen, for example bromine (Br), chlorine (Cl), iodine (I) or a combination of halogens.

Alternatively, the perovskite material of the active layer 107 is an organic perovskite material, for example formadiminium, also known as FA, with the chemical formula CN₅H₅₊, or methylammonium, also known as MA, with the chemical formula CH₃NH₃₊, or a combination of these elements.

According to one aspect of the described embodiments, the lower 105 and upper 109 charge transport layers are both made of inorganic materials. Encapsulating the active layer 107 with inorganic layers 105 and 109 improves the long-term stability of the perovskite material of layer 107, and hence the reliability and lifetime of the device.

For example, layer 105 is an electron-transport layer and layer 109 is a hole-transport layer. Layer 105 is, for example, titanium dioxide (TiO₂) or tin dioxide (SnO₂). Layer 109 is made, for example, of nickel oxide (NiO) or copper oxide (Cu₂O). Layers 105 and 109 are used to inject or collect current in active layer 107, so as to cause the diode to emit light or collect a photo-generated current. Alternatively, layers 105 and 109 can be inverted.

The lower electrode layer 103 is, for example, a metal layer, preferably a reflective metal layer. Layer 103 is made of platinum, for example.

The top electrode layer 111 is preferably a transparent conductive layer in the operating wavelength range of the optoelectronic or photovoltaic device. For example, layer 111 is made of a transparent conductive oxide, such as indium tin oxide (ITO), zinc oxide (ZNO), or zinc gallium oxide (GZO). Layer 111 can be doped with aluminum or cadmium. Layer 111 can be covered with a passivation layer, not shown, e.g. of silicon nitride.

FIG. 2 is a block diagram showing an example of a manufacturing method for the device shown in FIG. 1.

The method shown in FIG. 2 comprises successive steps of depositing layers 103, 105, 107, 109 and 111 on the upper surface of substrate 101. In a preferred embodiment, substrate 101 incorporates a control circuit of the diode formed the stack of layers 103, 105, 107, 109 and 111. Indeed, one advantage of the method shown in FIG. 2 is that it can be carried out entirely at relatively low temperatures, e.g. 400° C. or less, compatible with deposition on an integrated circuit previously formed in and on a semiconductor substrate, e.g. a silicon substrate. By way of example, substrate 101 is a CMOS-type integrated circuit. By way of example, a plurality of diodes, for example identical or similar, for example individually controllable, are formed on the top face of substrate 101. The diodes define pixels of the device, for example, and are connected to different electrical connection pads of the integrated circuit, respectively.

In a step 203, the lower electrode layer 103 is deposited on the upper surface of the substrate 101, for example by evaporation or sputtering.

In a step 205 subsequent to step 203, the lower charge transport layer 105 is deposited on the upper surface of the lower electrode layer 103. Preferably, layer 105 is deposited by PLD (Pulsed Laser Deposition), also known as pulsed laser ablation deposition. PLD deposition involves sputtering or ablating the surface of a target of the material to be deposited by means of a pulsed laser, so as to transfer the material into a plasma and then, via the plasma, onto the target substrate. One advantage of PLD deposition is that it enables complex materials with good crystalline quality to be deposited at a relatively low temperature, e.g. 400° C. or less, without damaging the target substrate.

Alternatively, the lower charge transport layer 105 is deposited by another deposition method, such as evaporation or sputtering, for example at a temperature of 400° C. or less.

In a step 207 subsequent to step 205, the active layer 107 is deposited on top of the charge transport layer 105. The active layer 107 is preferably deposited by PLD. In the case where the active layer 107 consists of a stack of multiple quantum wells, the quantum well layers and barrier layers are deposited successively by PLD, preferably without breaking the vacuum, i.e. by always keeping the substrate in a low-pressure enclosure, i.e. at a pressure lower than atmospheric pressure, for example at a pressure less than or equal to 1 mbar between successive deposition steps. This ensures that the individual layers of the stack are not exposed to air, moisture, oxygen or impurities between successive deposition steps. By way of example, quantum well layers and barrier layers are successively deposited by PLD without extracting the destination substrate from the deposition chamber between two successive deposition steps. Indeed, one advantage of PLD deposition is that it enables switching between different material targets of different compositions without extracting the destination substrate from the deposition chamber. Another advantage is that PLD deposition is a gentle deposition method. In other words, PLD deposition is characterized by a “soft landing” of the target atoms on the destination substrate. In particular, this avoids damaging the perovskite material of the quantum well layers during deposition of the barrier layers.

In a step 209 subsequent to step 207, the top charge transport layer 109 is deposited on the top surface of the active layer 107. According to one aspect of one embodiment, layer 109 is deposited by PLD deposition. Indeed, one advantage of PLD deposition is that it enables a charge-transport layer made of an inorganic material to be deposited on the active layer 107, without damaging the perovskite material of the layer 107, thanks to the fact that PLD deposition enables target atoms to land softly on the target surface. Preferably, the active layer 107 and the upper charge transport layer 109 are successively deposited by PLD deposition without breaking the vacuum between the deposition of layer 107 and the deposition of layer 109. In this way, the layer 107 is not exposed to air, oxygen or impurities before the layer 109 is deposited. By way of example, layer 107 and layer 109 are successively deposited by PLD deposition without changing the deposition equipment and without extracting the substrate from the deposition chamber between the deposition of layer 107 and the deposition of layer 109.

More preferably, the lower charge transport layer, the active layer 107 and the upper charge transport layer 109 are successively deposited by PLD deposition without breaking the vacuum between the depositions of the different layers, for example without changing the deposition equipment and without extracting the substrate from the deposition chamber between the depositions of the different layers.

By way of example, deposition of the upper charge transport layer 109 comprises at least a first phase during which the pressure in the deposition chamber is relatively high, for example greater than 0.01 mbar, preferably between 0.1 and 0.2 mbar. This ensures a soft landing of the target atoms on the surface of the active layer 107 and thus does not damage the active layer 107. At least during this first phase, the atmosphere in the deposition chamber is preferably oxygen-free, for example consisting essentially of argon and/or dinitrogen, so as not to oxidize the active layer 107. After this first phase, the pressure can be lowered, for example to around 0.001 mbar.

Another advantage of PLD deposition is that it enables the deposited materials to be epitaxial. In other words, the deposited layers exhibit lateral continuity (i.e. in the horizontal plane in the orientation of FIG. 1) of the crystal structure, or vertical crystal alignment between the different deposited layers. This improves the long-term stability of the device in general, and of the perovskite material in particular. Preferably, both the active layer 107 and the upper charge transport layer 109 are epitaxial. More preferably, the lower charge transport layer 105, the active layer 107 and the upper charge transport layer 109 are all epitaxial.

In a step 211 subsequent to step 209, the top electrode layer 111 is deposited on the top surface of the charge transport layer 109, for example by evaporation or sputtering.

Alternatively, the top electrode layer 111 is deposited by PLD, so as to obtain an epitaxial layer 111. Preferably, layer 109 and layer 111 are then deposited successively by PLD deposition without breaking the vacuum between the two depositions, for example without extracting the substrate from the deposition chamber between the two depositions. Similarly, the lower electrode layer 103 can be deposited by PLD in step 203.

In a particularly advantageous embodiment, layers 103, 105, 107, 109 and 111 are all deposited by PLD, so as to obtain a fully epitaxial stack, preferably without breaking the vacuum between the depositions of the different layers.

Various embodiments and variants have been described. The person skilled in the art will understand that certain features of these various embodiments and variants could be combined, and other variants will become apparent to the person skilled in the art. In particular, although the realization of a single diode has been described above, the skilled person will know how to implement processes enabling the simultaneous realization of several individually addressable diodes, corresponding for example to different pixels of a micro-screen or monolithic image sensor, using localized etching or localized deposition processes to electrically isolate the diodes from each other.

In addition, using localized etching or deposition processes, the skilled person will know how to produce, on the same substrate, several diodes based on different perovskite materials, corresponding to different pixels of a micro-screen emitting at different wavelengths, or to different pixels of an image sensor sensitive in different wavelength ranges.

Furthermore, in the embodiment described above in relation to FIG. 1, the substrate 101 and lower electrode 103 are opaque, although the embodiments described are not limited to this particular case. Alternatively, substrate 101 and lower electrode 103 can be transparent. The upper electrode 111 can then be either opaque or transparent.

In addition, the person skilled in the art will be capable of providing a tandem-type device, for example a photovoltaic device, comprising, between the lower electrode 103 and the upper electrode 111, a first diode formed by a stack of layers 105, 107 and 109, and a second diode formed by a stack of a third transport layer, an active layer and a fourth charge transport layer, not shown.

Furthermore, although examples of planar diodes have been described above, the embodiments may be adapted to devices based on three-dimensional diodes, for example LEDs based on semiconductor nanowires or microwires, or pyramidal LEDs, for example of the type described in patent application FR3087942 or in patent application FR3089687 previously filed by the applicant.

What is claimed is:

1. A method of manufacturing an optoelectronic or photovoltaic device, comprising the following successive steps:
a) forming, by PLD deposition, an active layer (107) comprising a perovskite material on the upper side of a first charge transport layer (105);
b) depositing, by PLD, a second charge-transport layer (109) of an inorganic material on the upper face of the active layer,
wherein steps a) and b) are carried out in a vacuum, i.e. at a pressure below atmospheric pressure, the method including no vacuum break between steps a) and b).

2. The method of claim 1, wherein the first charge transport layer (105) is deposited by PLD prior to step a).

3. The method of claim 2, wherein the step of depositing the first charge transport layer (105) and step a) are carried out under vacuum, i.e. at a pressure lower than atmospheric pressure, the process including no vacuum break between these two steps.

4. The method of claim 2 or 3, further comprising, prior to deposition of the first charge transport layer (105), a step of depositing a lower electrode (103), for example by PLD deposition, the first charge transport layer (105) then being deposited on the upper face of the lower electrode (103).

5. The method of any of claims 1 to 4, further comprising, after step b), a step of depositing a top electrode (111), for example by PLD deposition, on the top face of the second charge transport layer (109).

6. The method of claim 5, in which the top electrode (111) is made of a transparent conductive material.

7. The method of any of claims 1 to 6, wherein the second charge-transport layer (109) is made of titanium dioxide, tin dioxide, nickel oxide or copper oxide.

8. The method of any of claims 1 to 7, wherein the perovskite material of the active layer (107) is an inorganic perovskite material.

9. The method of claim 8, in which the perovskite material of the active layer (107) is an inorganic halogen perovskite material.

10. The method of any of claims 1 to 9, wherein, prior to step a), the first charge transport layer (105) is deposited on the top surface of an integrated circuit previously formed in and on a semiconductor substrate, for example a silicon substrate.

11. An optoelectronic or photovoltaic device comprising a vertical stack comprising a first charge transport layer (105), an active layer (107) comprising a perovskite material disposed on the upper side of the first charge transport layer, and a second charge transport layer (109) of an inorganic material disposed on the upper side of the active layer,
wherein the active layer (107) and the second charge transport layer (109) have crystal structures aligned in an epitaxial relationship.

12. The device of claim 11, wherein the first charge transport layer (105) is arranged on the top side of an integrated circuit formed in and on a semiconductor substrate, for example a silicon substrate.

13. The device of claim 11 or 12, wherein the active layer (107) is a solid monolayer of said perovskite material.

14. The device of any one of claims 11 to 13, wherein the active layer (107) is a stack of multiple quantum wells consisting of alternating quantum well layers of said perovskite material and barrier layers of another semiconductor material.
